(19) United States
(12) Patent Application Publication
(10) Pub. No.: US 2021/0365796 A1
(43) Pub. Date: Nov. 25, 2021

(54) METHOD AND SYSTEM FOR DETECTING ANOMALIES IN A SPECTROGRAM, SPECTRUM OR SIGNAL

(71) Applicant: Rohde & Schwarz GmbH & Co. KG, Munich (DE)

(72) Inventors: Baris Guezelarslan, Munich (DE); Dominik Hettich, Munich (DE)

(73) Assignee: Rohde & Schwarz GmbH & Co. KG, Munich (DE)

(21) Appl. No.: 17/233,229

(22) Filed: Apr. 16, 2021

(30) Foreign Application Priority Data
May 22, 2020 (EP) 20176074.1

(51) Int. Cl. G06N 3/08; G06N 3/04; G06F 17/18

(52) U.S. Cl. CPC G06N 3/088; G06F 17/18; G06N 3/0445

(57) ABSTRACT

A method for detecting anomalies in a spectrogram, spectrum or signal using a detection module having a first machine learning submodule, a second machine learning submodule and a comparison submodule is provided. The method includes: receiving the spectrogram, spectrum or signal as measured data by the detection module; generating filtered data based on the measured data by the first submodule; generating predicted data based on the measured data and/or the filtered data by the second submodule; and determining that the spectrogram, spectrum or signal includes an anomaly if the filtered data deviates from the measured data and/or the predicted data deviates from the measured data and/or the filtered data by at least a predetermined amount.

### FIELD OF THE DISCLOSURE

Embodiments of the present disclosure generally relate to a method for detecting anomalies in a spectrogram, spectrum or signal as well as to a system for detecting anomalies in a spectrogram, spectrum or signal.

### BACKGROUND

Techniques for detecting anomalies in spectrograms, spectra or signals are known in the art. However, such methods rely on prior knowledge of the anomalies to be detected. However, in many cases there is no prior knowledge of an anomaly that will occur so that prior art approaches cannot be used.

Thus, there is a need for a method and a system for detecting anomalies in a spectrogram, spectrum or signal reliably without prior knowledge of the anomalies SUMMARY

Embodiments of the present disclosure provide a method for detecting anomalies in a spectrogram, spectrum or signal using a detection circuit or module having a first machine learning submodule, a second machine learning submodule and a comparison submodule. The method comprises the following steps:

receiving the spectrogram, spectrum or signal, as measured data by the detection module;

generating filtered data based on the measured data by the first submodule;

comparing the filtered data with the measured data by the comparison submodule;

generating predicted data based on the measured data and/or the filtered data by the second submodule;

comparing the predicted data with the measured data and/or the filtered data; and

determining that the spectrogram, spectrum or a signal comprises an anomaly if the filtered data deviates from the measured data and/or the predicted data deviates from the measured data and/or the filtered data by at least a predetermined amount.

By creating filtered data and predicted data of the measured data it is possible to obtain a measure for the magnitude of the anomaly by analyzing the deviation of the measured data, the filter data and or the predicted data without any prior knowledge of the anomaly itself. Using the measure for the magnitude of the anomaly, a classification of the measured data towards the presence of anomalies or not can be reliably and quickly performed.

The determination step may be carried out by the comparison submodule.

The measured data, the filtered data and/or the predicted data are, for example, snapshots at a single point in time.

The predetermined amount may be different for different comparisons.

In an embodiment, the measured data, the filtered data and/or the predicted data are a graphical representation of the spectrogram, the spectrum or the signal, for example at a single point in time or a predefined time interval. Thus, the machine learning submodules are able to process the data efficiently.

The machine learning submodules, for example the first submodule, may be machine learning modules for visual pattern recognition. For example, the machine learning submodules process only the graphical information of the graphical representation. In some embodiments, they do not make use of the signal underlying the graphical representation itself, e.g. represented as I/Q data.

In order to reliably isolate the anomaly, the filtered data may be a denoised version of the measured data.

For example, the predicted data is a predicted version of the measured data and/or filtered data for a predetermined point in the future so that fluctuations in time may be taken into consideration by a comparison.

In an embodiment, the comparison submodule performs the comparison of data by calculating a cost value using a cost function, for example making use of the difference of the respective data, wherein it is determined that the spectrogram, spectrum or signal comprises an anomaly if the cost value exceeds a predefined threshold. By using a cost function, a resource efficient and fast analysis is achieved.

The cost function may be the same or different for different comparisons.

In an aspect, the comparison submodule obtains a first comparison result, for example a first cost value, by comparing the filtered data with the measured data and a second comparison result, for example a second cost value, by comparing the predicted data with the measured data and/or the filtered data. It is determined that the spectrogram, spectrum or a signal comprises an anomaly if either the first comparison result or the second comparison result, both comparison results, or a function of, for example a sum of the comparison results indicate(s) a deviation above a predetermined amount, for example the exceed(s) the respective predefined threshold. This way, the detection sensitivity may easily be adjusted using the threshold value.

The predefined threshold may be different for the first cost value than for the second cost value.

For example, the predefined amount, such as the predefined threshold, is set manually or has been determined by the detection module during training allowing a flexible use.

For efficient processing, the first submodule and/or the second submodule may comprise a pre-trained artificial neural network, for example wherein the first submodule and/or second submodule has been pre-trained with a training data set free of anomalies. In a further aspect, the training may be based on a graphical representation of a monitored frequency range over time, e.g. spectrograms.

In other words, the first and/or second submodule may be trained to process spectrograms solely graphically.

In an aspect, the first submodule comprises or is an autoencoder reliably generating filtered data without anomalies.

For an efficient prediction, the second submodule may be a recurrent artificial neural network, for example comprising a Long Short-Term Memory block.

In an aspect, the data of the training data set is a recorded data set, for example recorded data set that has been pre-processed to be free of anomalies, and/or the training data set is live data allowing a reliable and precise training of the artificial neural networks.

Training may be performed as part of the production process of the system as well as by the customer to adapt the system to the specific needs.

To allow a simple isolation of anomalies, the first submodule and/or second submodule is pre-trained to remove noise and/or anomalies from the measured data.

Embodiments of the present disclosure further provide a system for detecting anomalies in a spectrogram, spectrum or signal, comprising a detection circuit or module having a first machine learning submodule, a second machine learning submodule and a comparison submodule, wherein the detection module is configured to carry out a method as explained above.

The features and advantages discussed in context of the method also apply to the system and vice versa.

Naturally, the system, the detection module and its submodules are configured to carry out the method steps discussed in context of the method.

The detection module may comprise an input for receiving the spectrogram, spectrum or signal as measured data by the detection module and/or an output for outputting results.

For example, the system comprises a signal input and a processing unit, and in some embodiments the processing unit comprises the detection module reducing complexity.

The signal input may be connected to an antenna or a device under test.

In an aspect, the processing unit is configured to generate a graphical representation of a spectrogram, spectrum or a signal based on the signal received at the signal input. This way, the system is self-sufficient.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 shows a system according to the present disclosure;

FIG. 2 shows a detection module of the system according to FIG. 1;

FIG. 3 shows a flowchart of a method according to the present disclosure; and

FIG. 4 shows a flowchart of another embodiment of the method according to the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

FIG. 1 shows very schematically a system 10 for detecting anomalies in a spectrogram, spectrum or signal.

The system 10 may be, for example, a signal analyzer.

The system 10 comprises a signal input 12, a processing circuit or unit 14, a detection circuit or module 16 and an output device 30.

The signal input 12 may be connected to an antenna 18 for receiving the signals to be analyzed. The detection module 16 may be implemented in the processing unit 14 (illustrated with dashed lines in FIG. 1) or is a separate circuit or module.

Therein and in the following, the term “module” is understood to describe suitable hardware, suitable software, or a combination of hardware and software that is configured to have a certain functionality.

The hardware may, inter alia, comprise a CPU, a GPU, an FPGA, an ASIC, or other types of electronic circuitry.

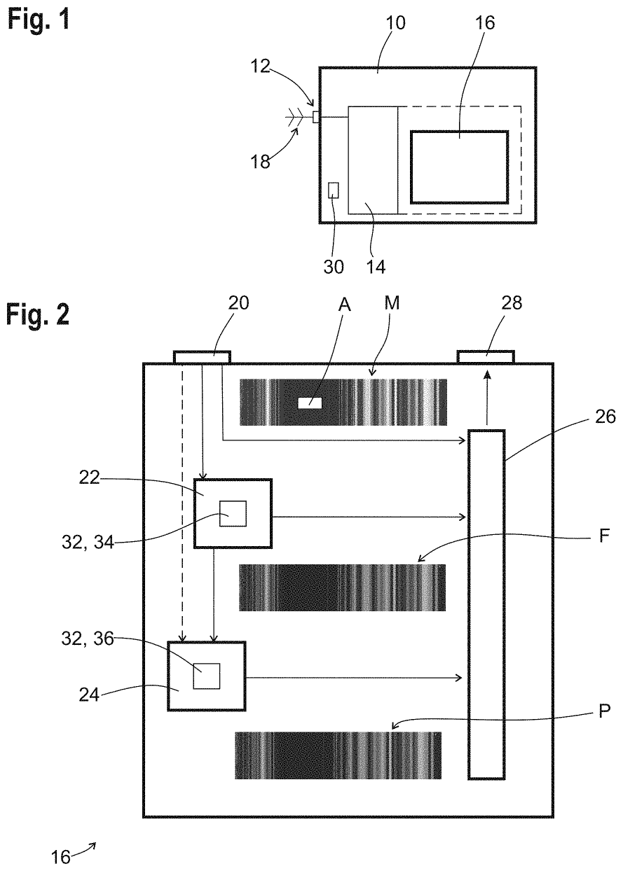

A detection module 16 is shown schematically in more detail in FIG. 2.

In the embodiment shown in FIG. 2, the data processed by the detection module 16 is a spectrogram, more precisely a graphical representation of a spectrogram.

Of course, the detection module 16 may be also be configured to process spectra or measured signals, for example graphical representations of spectra or signals.

The detection module 16 comprises an input 20 connected to the processing unit 14 or other parts of the processing unit 14, a first machine learning submodule 22, a second machine learning submodule 24, a comparison submodule 26 and an output 28.

The output 28 of the detection module 16 is connected to the processing unit 14, other parts of the processing unit 14 and/or the output device 30 of the system 10, for example a display.

The first machine submodule 22 comprises an artificial neural network 32, for example a convolutional artificial neural network configured as an autoencoder 34.

The first submodule 22 has been pre-trained to remove noise and/or anomalies from data.

The second machine learning submodule 24 comprises a recurrent artificial neural network 36 which comprises a Long Short Term Memory (LSTM) block or is configured as a Long Short Term Memory network.

The second submodule 24 has been pre-trained to generate a data set based on the input data set which is a prediction of the spectrogram inputted to the second submodule 24 for a predetermined interval in the future.

The second machine learning submodule 24 has also been pre-trained, for example with the same training data set or a same kind of training data set as the first submodule 22.

The training data set for the first submodule 22 comprises exclusively data (spectrograms, spectra or signals) not having noise or anomalies so that the autoencoder 34 is trained to output data (spectrograms, spectra or signals) without or lesser noise or anomalies, i.e. denoised data.

Thus, the first submodule 22, i.e. the autoencoder 34, may be regarded as a filter filtering out noise or anomalies from data, for example purely graphically.

The training data may comprise spectrograms from recorded signal data which have been preprocessed to remove anomalies and/or noise, for example by classical filters. The training set may also be spectrograms generated from live data, i.e. from a very stable and low noise source.

The training data set for training the second submodule 24 may also be free of anomalies and/or noise and comprises a set of input spectrograms and associated correct predicted spectrograms.

Thus, the first submodule 22 and the second submodule 24 may be trained using graphical representations or visual representation of signal data only, i.e. without information about the underlying signal itself (e.g. I/Q data). The submodules will therefore be trained to perform a purely graphical operation to filter or to predict.

Training of the first submodule 22 and the second submodule 24 may be performed as part of the production process of the system 10 as well as by the customer to adapt the system 10 to the specific needs.

The input of the first submodule 22 is connected to the input 20 of the detection module 16, and the second submodule 24 is connected to the output of the first submodule 22. Additionally or alternatively, the second submodule 24 is also connected to the input 20 as indicated with dashed lines in FIG. 2.

The input of the comparison submodule 26 is connected to the input 20, the first submodule 22 and the second submodule 24. The output of the comparison submodule 26 is connected to the output 28 of the detection module 16.

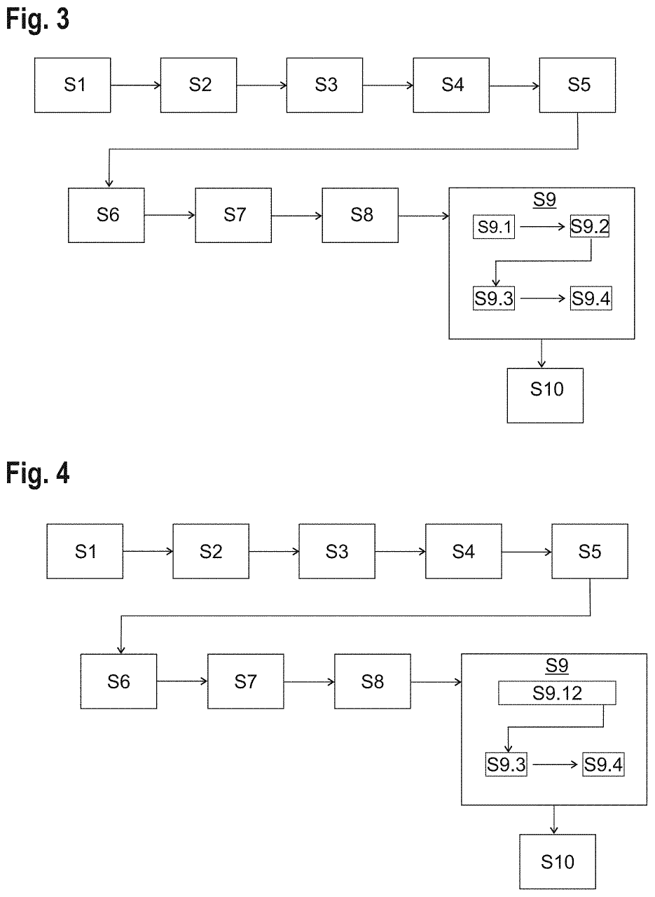

For detecting anomalies A in a spectrogram, spectrum or signal the system 10 performs the method shown in FIG. 3.

Firstly, in step S1 the system 10 receives the signal or data to be analyzed via the signal input 12.

This may be, for example, radio signals received by the antenna 18.

In step S2, the processing unit 14 processes the signal to generate a graphical representation of a spectrogram, spectrum or signal of the signal received at the signal input 12. The graphical representation is then, in step S3 transmitted to the input 20 of the detection module 16 and are regarded as the measured data M (see FIG. 2) by the detection module 16.

In FIG. 2, only spectrograms are shown to exemplify the method. Of course, the method may also be performed with spectrums or signals instead.

Thus, the detection module 16 receives the measured data M (step S4).

The measured data M is received from the first submodule 22 and processed by the first submodule 22 (step S5). As the first submodule 22 has the architecture of an autoencoder 34 and has been pre-trained to reduce noise and/or anomalies from input data, the first submodule 22 generates filtered data F of the measured data M that does not include noise and anomalies A.

The filtered data F is then transmitted to the second submodule 24 as input data (step S6).

Additionally or alternatively, the second submodule 24 receives the measured data M instead or as well.

In step S7, the second submodule 24 generates predicted data P, i.e. a predicted spectrogram of the evolution of the filtered data F at the predicted point in time, the measured data M or based on both filtered data F and measured data M.

Thus, the predicted data P is a predicted version of the measured data M and/or filtered data F for a predetermined point in the future, i.e. at a predetermined interval in the future.

The measured data M, the filtered data F and the predicted data P are snapshots of a single point in time of the signal or data received at the signal input 12 of the system 10.

In step S8, which of course may also have been performed earlier in parts, the measured data M, the filtered data F and the predicted data P are transmitted to the comparison submodule 26.

In step S9 the comparison submodule 26 determines whether or not the measured data M comprises an anomaly A and outputs its result to the output 28 of the detection module 16.

The output device 30 then outputs a signal accordingly (step S10).

In the first embodiment, the comparison submodule 26 comprises two cost functions.

Using the first cost function, the comparison submodule 26 compares the filtered data F with the measured data M yielding a cost value representing the magnitude of the anomalies A that have been removed by the first submodule 22 (step S9.1).

For example, the cost value is the sum of the squared differences of the filtered data F and the measured data M on a pixel-by-pixel basis.

Likewise, the comparison submodule 26 uses the second cost function which may be the same or different from the first cost function i.e. to compare the predicted data P with the measured data M or the filtered data F (step S9.2).

In step S9.3, the first cost value and the second cost value are compared against predetermined thresholds.

The thresholds may be the same or different for each cost function and the resulting in cost value.

The predetermined thresholds may have been manually set by the user of the system 10.

It is also conceivable, that they have been determined by the detection module 16 during training (aka they have been learned), i.e. that the detection module 16 has been trained with training data comprising measured data M and correct indications of the present of an anomaly A.

For example, the comparison submodule 26 is also an artificial neural network or the submodules 22, 24, 26 are a single artificial neural network so that the threshold may be trained or learned.

The comparison submodule 26 determines in step S9.3 if the first cost value, the second cost value or both cost values are equal to or lie above their respective predetermined thresholds.

Of course, the comparisons (step S9.2) and determination (step S9.3) does not have to be performed en bloc but may be performed as soon as possible, i.e. calculating the first cost value may be performed as soon as the filtered data F is obtained without waiting on the results of the second submodule 24.

If so, the comparison submodule 26 determines in step 9.4 that the measured data M have an anomaly A. This result is then transmitted via output 28 of the detection module 16 in a suitable manner.

As the cost values are a measure for the deviation between the compared data, the threshold indicates that the deviation between the data has exceeded a predetermined amount of deviation.

It is also possible that the first and second cost values are not compared separately to thresholds but that a function, for example the sum, of the cost values is obtained and compared against a respective threshold.

When comparing a function of the first and second cost value with a threshold, complex dependencies of the anomalies in frequency and time may be taken into account.

By comparing the measured data M comprising a potential anomaly A with the filtered data F and the predicted data P not comprising the anomaly A due to the operations by the first and/or second submodule 22, 24, the anomaly A is extracted and represented as a cost value which is, at the same time, a measure for the magnitude of the anomaly A.

Using the first submodule 22, frequency anomalies can be determined and by using the second submodule 26 anomalies in time can be detected.

FIG. 4 shows a second embodiment of the method according to the present disclosure which corresponds to the first embodiment of the method in most parts. Thus, in the following only the differences are discussed and the same elements and methods steps are references to with the same reference signs.

In the second embodiment of the method, the comparison submodule 26 uses a single, global cost function to determine whether the filtered data F deviates from the measured data M and whether the predicted data P deviates from the measured data M and/or the filtered data F.

Thus, in step S9, the comparison submodule 26 determines a global cost value based on the global cost function in step S9.12. Then, in steps S9.3 and S9.4 the comparison submodule 26 compares the global cost value against a global threshold and determines that an anomaly A is present in the measured data M if the global cost value is equal to or above the global threshold.

Certain embodiments disclosed herein, for example the respective module(s), utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes one or more processors or portions thereof and accompanying software, firmware, hardware, and the like.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method for detecting anomalies in a spectrogram, spectrum or signal using a detection module having a first machine learning submodule, a second machine learning submodule and a comparison submodule, the method comprising:
receiving the spectrogram, spectrum or signal, as measured data by the detection module;
generating filtered data based on the measured data by the first submodule;
comparing the filtered data with the measured data by the comparison submodule;
generating predicted data based on at least one of the measured data and the filtered data by the second submodule;
comparing the predicted data with at least one of the measured data and the filtered data; and
determining that the spectrogram, spectrum or signal comprises an anomaly if the filtered data deviates from the measured data and/or the predicted data deviates from at least one of the measured data and the filtered data by at least a predetermined amount.

2. The method according to claim 1, wherein at least one of the measured data, the filtered data, and the predicted data are a graphical representation of the spectrogram, the spectrum or the signal.

3. The method according to claim 2, wherein at least one of the measured data, the filtered data, and the predicted data are a graphical representation of the spectrogram at a single point in time or a predefined time interval.

4. The method according to claim 1, wherein the filtered data is a denoised version of the measured data.

5. The method according to claim 1, wherein the predicted data is a predicted version of the measured data and/or filtered data for a predetermined point in the future.

6. The method according to claim 1, wherein the comparison submodule performs the comparison of data by calculating a cost value using a cost function, wherein it is determined that the spectrogram, spectrum or a signal comprises an anomaly if the cost value exceeds a predefined threshold.

7. The method according to claim 6, wherein the comparison submodule performs the comparison of data by calculating the cost value using the cost function making use of the difference of the respective data.

8. The method according to claim 1, wherein the comparison submodule obtains a first comparison result by comparing the filtered data with the measured data and a second comparison result by comparing the predicted data with the measured data and/or the filtered data,
wherein it is determined that the spectrogram, spectrum or a signal comprises an anomaly if either the first comparison result or the second comparison result, both comparison results, or a function of the comparison results indicate(s) a deviation above a predetermined amount.

9. The method according to claim 8, wherein the first comparison result is a first cost value or the second comparison result is a second cost value.

10. The method according to claim 8, wherein the function of the comparison results comprises a sum of the comparison results.

11. The method according to claim 1, wherein the predefined amount is set manually or has been determined by the detection module during training.

12. The method according to claim 1, wherein the first submodule and/or the second submodule comprises a pre-trained artificial neural network.

13. The method according to claim 12, wherein the first submodule comprises or is an autoencoder.

14. The method according to claim 12, wherein the second submodule is a recurrent artificial neural network.

15. The method according to claim 12, wherein the data of the training data set is at least one of a recorded data set, and live data.

16. The method according to claim 15, wherein the data of the training data set is a recorded data set that has been pre-processed to be free of anomalies.

17. The method according to claim 1, wherein at least one of the first submodule and the second submodule is pre-trained to remove noise and/or anomalies from the measured data.

18. A system for detecting anomalies in a spectrogram, spectrum or signal, the system comprising a detection module having a first machine learning submodule, a second machine learning submodule and a comparison submodule, wherein the detection module is configured to carry out a method according to claim 1.

19. The system according to claim 18, wherein the system comprises a signal input and a processing unit.

20. The system according to claim 19, wherein the processing unit is configured to generate a graphical representation of a spectrogram, spectrum or signal based on the signal received at the signal input.
